(19) United States
(12) Patent Application Publication
(10) Pub. No.: US 2007/0172968 A1
(43) Pub. Date: Jul. 26, 2007

(54) Method of processing semiconductor substrate

(75) Inventors: Sung-woo Kang, Suwon-si (KR); In-sik Chin, Seoul (KR); Won-soo Choi, Seongnam-si (KR)

Correspondence Address: MILLS & ONELLO LLP, ELEVEN BEACON STREET, SUITE 605, BOSTON, MA, 02108, US

(73) Assignee: Samsung Electronics Co., Ltd.

(21) Appl. No.: 11/651,863

(22) Filed: Jan. 10, 2007

(30) Foreign Application Priority Data
Jan. 11, 2006 (KR) 10-2006-0003099

(51) Int. Cl. H01L 21/66; H01L 21/302

(52) U.S. Cl. 438/14; 438/707; 257/E21.252; 257/E21.53

(57) ABSTRACT

A method of processing a semiconductor substrate for manufacturing a semiconductor device includes: obtaining pattern density information of the semiconductor product; applying the pattern density information to a previously determined relation between pattern densities and etch parameters so as to obtain process conditions for the semiconductor product; and etching the semiconductor substrate under the process conditions.

### CROSS-REFERENCE TO RELATED PATENT APPLICATION

This application claims the benefit of Korean Patent Application No. 10-2006-0003099, filed on Jan. 11, 2006, in the Korean Intellectual Property Office, the contents of which are incorporated herein in their entirety by reference.

### BACKGROUND OF THE INVENTION

1. Field of the Invention

The present invention relates to a method of processing a semiconductor substrate, and more particularly, to a feedback method of processing a semiconductor substrate.

2. Description of the Related Art

Various types of semiconductor devices are often manufactured on a single production line. However, process conditions cannot be optimized for all the types of semiconductor devices manufactured on the production line. Accordingly, since optimized process conditions used for manufacturing relatively mass produced types of semiconductor devices are generally set as default conditions, relatively small production type semiconductor devices cannot be manufactured with the optimized process conditions. As a result, errors in the small production type of semiconductor devices increasingly occur during the manufacturing processes, and in particular, the errors are liable to occur more frequently under recent strict design rules.

The pattern density is defined as a percentage of the area to be etched with respect to the entire area of a semiconductor device. Referring to FIG. 1, when semiconductor devices are etched with the same etch conditions, as the pattern density of the semiconductor device increases, the etch depth of the semiconductor device approximately linearly decreases. Referring to FIG. 2A, when a semiconductor substrate including a silicon layer 2 is etched using a mask pattern 1 having a relatively high pattern density as an etch mask, a trench having a shallower etch depth D1 than a target etch depth D is formed. Referring to FIG. 2B, when a semiconductor substrate including a silicon layer 4 is etched using a mask pattern 3 having a relatively low pattern density as an etch mask, a trench having a deeper etch depth D2 than a target etch depth D is formed. Although various types of semiconductor devices are desirably etched to a uniform depth, a relatively small production type of semiconductor devices may be etched shallower or deeper than a target etch depth according to the pattern density of the relatively small production type of semiconductor devices.

### SUMMARY OF THE INVENTION

The present invention provides a method of processing a semiconductor substrate for manufacturing a semiconductor device.

According to an aspect of the present invention, there is provided processing a semiconductor substrate for manufacturing a semiconductor device comprising: obtaining pattern density information of a first type semiconductor device; applying the pattern density information to a previously determined relation between pattern densities and etch parameters for a second type semiconductor device so as to approximate process conditions for the first type semiconductor device; and etching the semiconductor substrate of the first type semiconductor device under the approximated process conditions.

In one embodiment, the pattern density information is obtained from a mask design pattern file generated by a commercial layout tool.

In one embodiment, the first type semiconductor device is a semiconductor device to be produced in small quantity and the second type semiconductor device is a semiconductor device to be produced in relatively mass quantity.

In one embodiment, the approximated process conditions comprise chamber temperature, chamber pressure, etch gas species, etch gas flow rate, etching time, electric power and magnetic strength.

In one embodiment, the previously determined relation is a trend line obtained from the distribution set of pattern densities and etch parameters.

In one embodiment, processing the semiconductor substrate is performed for trench formation.

According to other aspect of the present invention, there is provided a method of processing a semiconductor substrate for manufacturing a semiconductor device comprising: obtaining pattern density information of a first type semiconductor device; applying the pattern density information to a previously determined relation between pattern densities and etch parameters for a second type semiconductor device so as to approximate process conditions for the first type semiconductor device; etching a first semiconductor substrate of the first type semiconductor device under the approximated process conditions; measuring an etch result of the first semiconductor substrate, wherein the etch result comprises etched depth and etch rate; comparing the etch result with a process target of the first type semiconductor device to determine whether the etch result is outside a tolerance range; modifying the approximated process condition by the etch result, if the etch result is outside the tolerance range required for the first type semiconductor device; and etching a second semiconductor substrate for the first type semiconductor device under the modified process condition.

In one embodiment, the pattern density information is obtained from a mask design pattern file generated by a commercial layout tool.

In one embodiment, the step of measuring the etch result of the semiconductor substrate through the step of etching the second semiconductor substrate is repeated until the etch result becomes inside the tolerance.

In one embodiment, the first type semiconductor device is a semiconductor device to be produced in small quantity and the second type semiconductor device is a semiconductor device to be produced in relatively mass quantity.

In one embodiment, the approximated process conditions comprise chamber temperature, chamber pressure, etch gas species, etch gas flow rate, etching time, electric power and magnetic strength.

In one embodiment, the previously determined relation is a trend line obtained from the distribution set of pattern densities and etch parameters.

In one embodiment, processing the semiconductor substrate is performed for trench formation.

### BRIEF DESCRIPTION OF THE DRAWINGS

The foregoing and other objects, features and advantages of the invention will be apparent from the more particular description of preferred aspects of the invention, as illustrated in the accompanying drawings in which like reference characters refer to the same parts throughout the different views. The drawings are not necessarily to scale, emphasis instead being placed upon illustrating the principles of the invention. In the drawings, the thickness of layers and regions are exaggerated for clarity.

FIG. 1 is a graph of the relationship between pattern density and etch depth of semiconductor devices under the same process condition.

FIG. 2A is a cross-sectional view of a semiconductor device etched shallower than a target etch depth using a conventional technique.

FIG. 2B is a cross-sectional view of a semiconductor device etched deeper than a target etch depth using a conventional technique.

FIG. 3 is a flowchart illustrating a method of processing a semiconductor substrate for manufacturing a semiconductor device according to embodiments of the present invention.

FIG. 4 is a flowchart illustrating a method of processing a semiconductor substrate for manufacturing a semiconductor device according to other embodiments of the present invention.

### DETAILED DESCRIPTION OF THE INVENTION

FIG. 3 is a flowchart illustrating a method of processing a semiconductor substrate for manufacturing a semiconductor device according to embodiments of the present invention. Referring to FIG. 3, pattern density information of a first type semiconductor device is obtained in step 301. The pattern density information of the first type semiconductor device can be obtained from a mask design pattern file in GDS-II format generated by commercial lay out tools, for example, OrCad, AutoDesk, Cadence, and the like.

The pattern density information is applied to a previously determined relation between pattern densities and etch parameters for a second type semiconductor device so as to obtain process conditions for the first semiconductor device in step 302. The first type semiconductor device can be a semiconductor device to be produced in small quantity and the second type semiconductor device can be a semiconductor device to be produced in relatively mass quantity. The etch parameters can include etch rate or etch depth.

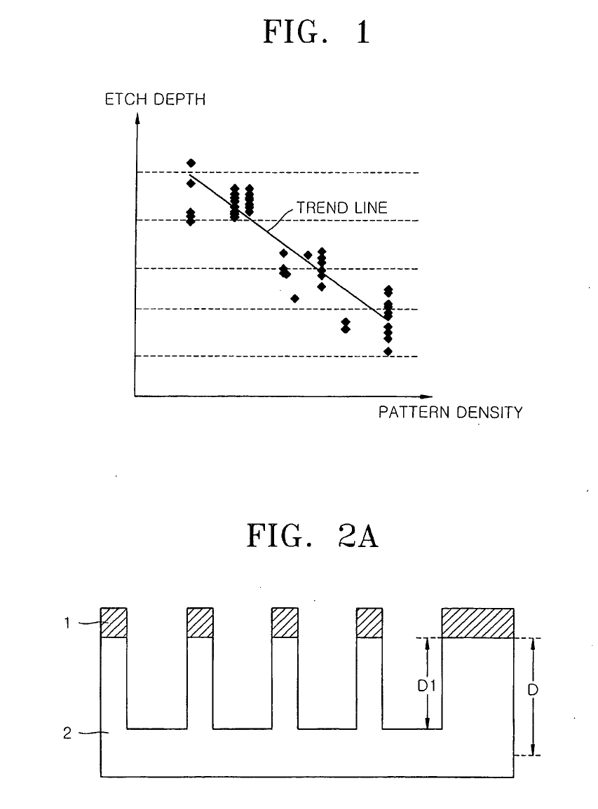

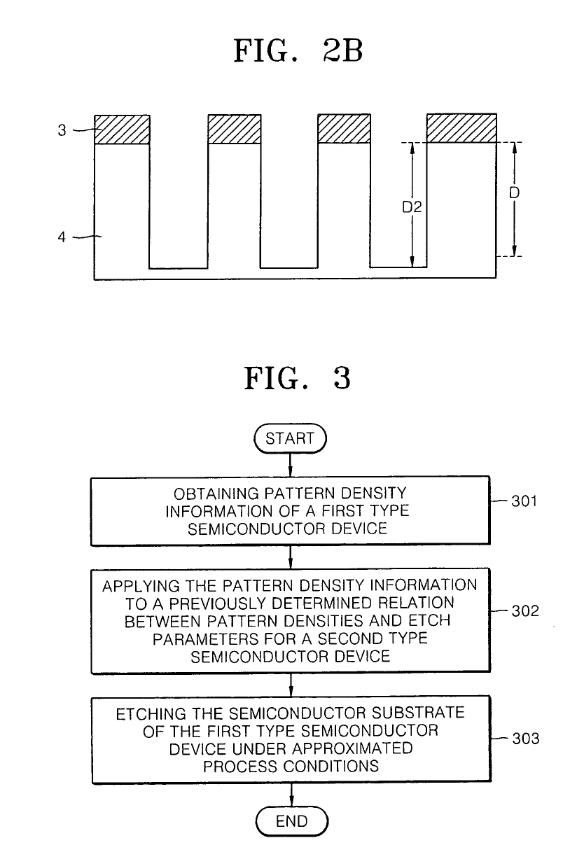

The previously determined relation is obtained from the graph of the relationship between pattern density and etch depth illustrated in FIG. 1. The relationship can be defined by a trend line statistically obtained from the distribution set of pattern densities and etch parameters. The trend line can be readily obtained by commercial statistical tools, for example Microsoft Excel of Microsoft Corporation. The distribution set of pattern densities and etch parameters can be obtained from a plurality of measured etch results of a relatively mass produced type of semiconductor devices under a process condition optimized for the mass produced type of semiconductor devices.

The process conditions may include at least one of chamber temperature, chamber pressure, etch gas species, etch gas flow rate, etching time, electric power and magnetic strength. The pattern density information of the semiconductor device to be produced in small quantity is applied to the trend line and, then, the approximated etch parameters, for example etch rate or etch depth, can be obtained. Thus, the approximated process condition for the first type semiconductor device can be obtained from the approximated etch parameters. Finally, the first type semiconductor can be manufactured by processing a semiconductor substrate under the approximated process conditions in step 303.

According to example embodiments of the present invention, the process conditions for processing the semiconductor substrate for the semiconductor device to be produced in small quantity can be readily approximated from the process condition optimized for the mass produced type of semiconductor devices by applying the pattern density information to the previously determined relation between pattern densities and etch parameters. In particular, for the formation of trenches for shallow trench isolation of the first type semiconductor devices, the approximated process conditions are useful.

However, etch results for etch processes performed under the approximated process condition can deviate from a process target of the first type semiconductor device. In this case, the approximated process conditions are modified to obtain a better process result for the first type semiconductor device.

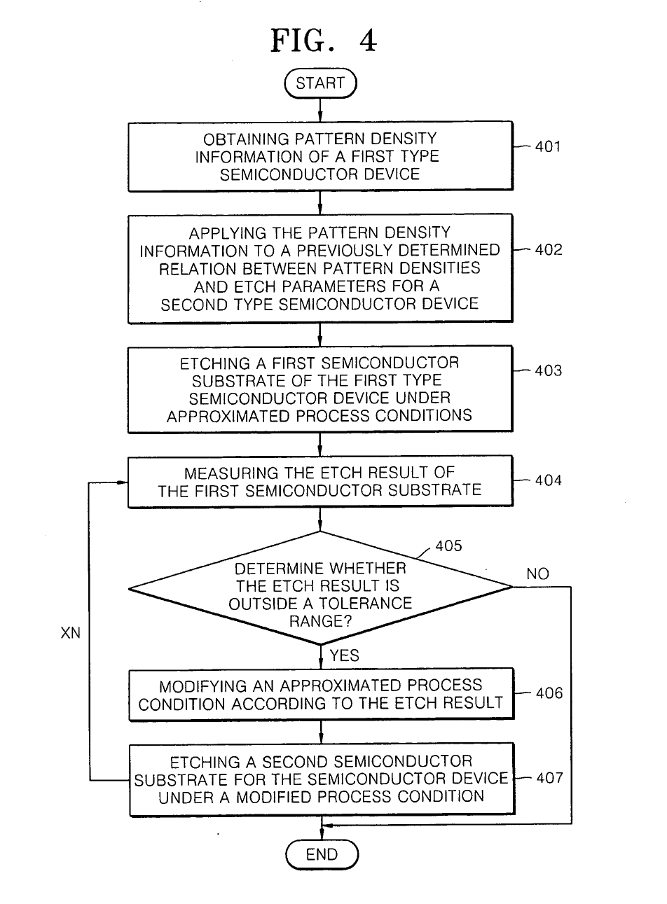

FIG. 4 is a flowchart illustrating a method of processing a semiconductor substrate for manufacturing a semiconductor device according to other embodiments of the present invention. Referring to FIG. 4, the method of processing a semiconductor substrate for manufacturing a semiconductor device includes the steps 401, 402 and 403, respectively identical to the steps 301, 302 and 303 illustrated in FIG. 3. As described in connection with FIG. 3, the first type semiconductor device is a semiconductor device to be produced in small quantity and the second type semiconductor device is a semiconductor device to be produced in relatively mass quantity.

According to the other embodiments of the present invention, the method of processing a semiconductor substrate for manufacturing a semiconductor device can further comprise steps 404-407 modifying the approximated process condition for the first type semiconductor device.

After a first semiconductor substrate of the first type semiconductor device is etched under the approximated process conditions in step 403, an etch result of the first semiconductor substrate is measured in step 404. The etch result can comprise etched depth and etch rate. Then, the etch result can be compared with a process target of the first type semiconductor device to determine whether the etch result is outside a tolerance range required for the first type semiconductor device in step 405.

If the etch result is outside the tolerance range, the approximated process condition such as chamber temperature, chamber pressure, etch gas species, etch gas flow rate, etching time, electric power and magnetic strength, can be modified according to the etch result in step 406. For example, when the first substrate processed under the approximated process condition is known to be so less etched as to be outside the tolerance by measuring the etch result, the approximated process condition such as etching time might be modified by increasing the etching time. Then, a second semiconductor substrate for the first semiconductor device can be etched under the modified process condition in step 407.

In some embodiments of the present invention, step 404 through step 407 can be repeated until the etch result is inside the tolerance range. Accordingly, the modified process condition can converge to an optimized process condition for the first type semiconductor device. Thus, a better process result can be obtained in manufacturing the first type semiconductor device.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A method of processing a semiconductor substrate for manufacturing a semiconductor device, the method comprising:
obtaining pattern density information of a first type semiconductor device;
applying the pattern density information to a previously determined relation between pattern densities and etch parameters for a second type semiconductor device so as to approximate process conditions for the first type semiconductor device; and
etching the semiconductor substrate of the first type semiconductor device under the approximated process conditions.

2. The method of claim 1, wherein the approximated process conditions comprise chamber temperature, chamber pressure, etch gas species, etch gas flow rate, etching time, electric power and magnetic strength.

3. The method of claim 1, wherein the previously determined relation is a trend line obtained from the distribution set of pattern densities and etch parameters.

4. The method of claim 1, wherein the processing the semiconductor substrate is performed for trench formation.

5. The method of claim 1, wherein the pattern density information is obtained from a mask design pattern file generated by a commercial layout tool.

6. The method of claim 5, wherein the approximated process conditions comprise chamber temperature, chamber pressure, etch gas species, etch gas flow rate, etching time, electric power and magnetic strength.

7. The method of claim 5, wherein the previously determined relation is a trend line obtained from the distribution set of pattern densities and etch parameters.

8. The method of claim 5, wherein the processing the semiconductor substrate is performed for trench formation.

9. The method of claim 1, wherein the first type semiconductor device is a semiconductor device to be produced in small quantity and the second type semiconductor device is a semiconductor device to be produced in relatively mass quantity.

10. The method of claim 9, wherein the approximated process conditions comprise chamber temperature, chamber pressure, etch gas species, etch gas flow rate, etching time, electric power and magnetic strength.

11. The method of claim 9, wherein the previously determined relation is a trend line obtained from the distribution set of pattern densities and etch parameters.

12. The method of claim 9, wherein the processing the semiconductor substrate is performed for trench formation.

13. A method of processing a semiconductor substrate for manufacturing a semiconductor device, the method comprising:
obtaining pattern density information of a first type semiconductor device;
applying the pattern density information to a previously determined relation between pattern densities and etch parameters for a second type semiconductor device so as to approximate process conditions for the first type semiconductor device;
etching a first semiconductor substrate of the first type semiconductor device under the approximated process conditions;
measuring an etch result of the first semiconductor substrate, wherein the etch result comprises etched depth and etch rate;
comparing the etch result with a process target of the first type semiconductor device to determine whether the etch result is outside a tolerance range;
modifying the approximated process condition according to the etch result, if the etch result is outside the tolerance range required for the first type semiconductor device; and
etching a second semiconductor substrate for the first type semiconductor device under the modified process condition.

14. The method of claim 13, wherein the approximated process conditions comprise chamber temperature, chamber pressure, etch gas species, etch gas flow rate, etching time, electric power and magnetic strength.

15. The method of claim 13, wherein the previously determined relation is a trend line obtained from the distribution set of pattern densities and etch parameters.

16. The method of claim 13, wherein processing the semiconductor substrate is performed for trench formation.

17. The method of claim 13, wherein the pattern density information is obtained from a mask design pattern file generated by a commercial layout tool.

18. The method of claim 17, wherein the approximated process conditions comprise chamber temperature, chamber pressure, etch gas species, etch gas flow rate, etching time, electric power and magnetic strength.

19. The method of claim 17, wherein the previously determined relation is a trend line obtained from the distribution set of pattern densities and etch parameters.

20. The method of claim 17, wherein processing the semiconductor substrate is performed for trench formation.

21. The method of claim 13, wherein the step of measuring the etch result of the semiconductor substrate through the step of etching the second semiconductor substrate is repeated until the etch result becomes inside the tolerance.

22. The method of claim 21, wherein the approximated process conditions comprise chamber temperature, chamber pressure, etch gas species, etch gas flow rate, etching time, electric power and magnetic strength.

23. The method of claim 21, wherein the previously determined relation is a trend line obtained from the distribution set of pattern densities and etch parameters.

24. The method of claim 21, wherein processing the semiconductor substrate is performed for trench formation.

25. The method of claim 13, wherein the first type semiconductor device is a semiconductor device to be produced in small quantity and the second type semiconductor device is a semiconductor device to be produced in relatively mass quantity.

26. The method of claim 25, wherein the approximated process conditions comprise chamber temperature, chamber pressure, etch gas species, etch gas flow rate, etching time, electric power and magnetic strength.

27. The method of claim 25, wherein the previously determined relation is a trend line obtained from the distribution set of pattern densities and etch parameters.

28. The method of claim 25, wherein processing the semiconductor substrate is performed for trench formation.
